(19) United States
(12) Patent Application Publication
(10) Pub. No.: US 2006/0105537 A1
(43) Pub. Date: May 18, 2006

(54) Method for forming storage electrode of semiconductor device

(75) Inventors: Ki Won Nam, Gyeonggi-do (KR); Kyung Won Lee, Seoul (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/148,559

(22) Filed: Jun. 9, 2005

(30) Foreign Application Priority Data
Nov. 18, 2004 (KR) 10-2004-0094635

(51) Int. Cl. H01L 21/20

(52) U.S. Cl. 438/396; 257/E21.02

(57) ABSTRACT

A method for forming a storage electrode of a semiconductor device is provided, the method including forming an oxide film on a lower insulating layer disposed on a semiconductor substrate, forming a hard mask silicide layer pattern defining a strode electrode region on the oxide film, subjecting the hard mask silicide layer to a cleaning process to recess the hard mask silicide layer pattern, and etching the oxide film using the recessed hard mask silicide layer pattern as an etching mask until a landing plug is exposed to form a storage electrode.

### BACKGROUND OF THE INVENTION

1. Field of the Invention

The present invention generally relates to a method for forming a storage electrode of a semiconductor device, and more specifically, to a method for forming a storage electrode of a semiconductor device wherein a surface area of a storage electrode region is increased by etching a surface of a hard mask layer pattern used as an etching mask, thereby preventing a damage to an oxide film for the storage electrode and a bridge between the neighboring storage electrodes.

2. Description of the Related Art

Recently, a size of a cell of a semiconductor device is decreased as an integration density of the semiconductor device is increased. As a result, it is difficult to obtain a sufficient electrostatic capacitance that is proportional to a surface area of a storage electrode.

A unit cell of a DRAM device comprises a MOS transistor and a capacitor. In fabrication of the DRAM device, it is important to increase in the electrostatic capacitance of the capacitor as well as decrease in the size of the device.

The electrostatic capacitance of the capacitor can be expressed as the following equation.

$$Capacitance = \frac{{E}_{o} \times {E}_{r} \times A}{T} ,$$

where Eₒ is a dielectric constant in vacuum, Eᵣ is a dielectric constant in a dielectric film, A is an area of the capacitor, and T is a thickness of the dielectric film.

In order to increase the electrostatic capacitance of the capacitor, the surface area of a lower storage electrode must be increased or the thickness of the dielectric film must be decreased.

FIGS. 1a through 1c illustrate a conventional method for forming a storage electrode of a semiconductor device.

Referring to FIG. 1a, a lower insulating film 11 is formed on a semiconductor substrate (not shown) including a device isolation film (not shown), a gate electrode (not shown), a landing plug (not shown) and a bit line (not shown).

Next, an oxide film comprising a stacked structure of a PSG film 13 and a planarized TEOS film 15 is formed on the lower insulating film 11. Here, the TEOS film 15 is formed using a plasma enhanced chemical vapor deposition (“PECVD”) method.

Thereafter, a hard mask layer pattern 17 is formed on the planarized TEOS film 15.

Here, a polysilicon film (not shown) is deposited on the planarized TEOS film 15, then etched via a lithography and etching process using a storage electrode mask. Thereafter, the etched polysilicon film is subjected to a cleaning process using a Buffer Oxide Etchant (“BOE”) to form a hard mask layer pattern 17.

Referring to FIG. 1b, the oxide film is etched using the hard mask layer pattern 17 as an etching mask until a lading plug (not shown) in the lower insulating layer 11 is exposed to form a storage electrode region 19.

Referring to FIG. 1c, the hard mask layer pattern 17 is removed. The storage electrode region 19 is then subjected to a cleaning process to increase a surface area of the storage electrode region 19.

At this time, the cleaning process causes a bowing phenomenon of the oxide film for a storage electrode and irregular loss of the oxide film denoted as ‘B’ due to a cleaning solution. Here, ‘A’ depicts a surface area of the oxide film prior to the cleaning process.

Next, a conductive layer for a storage electrode is deposited in a subsequent process. The adjacent conductive layers for the storage electrode in the storage electrode region 19 are then bridged.

FIGS. 2a through 2c illustrate another conventional method for forming a storage electrode of a semiconductor device.

Referring to FIG. 2a, a lower insulating film 21 is formed on a semiconductor substrate (not shown) including a device isolating film (not shown), a gate electrode (not shown), a landing plug (not shown) and a bit line (not shown).

Next, an oxide film having a stacked structure of a PSG film 23 and a planarized TEOS film 25 is formed on the lower insulating film 21. Here, the TEOS film 25 is formed using a PECVD method.

Thereafter, a hard mask layer pattern 27 is formed on the planarized TEOS film 25.

Here, a polysilicon film (not shown) is deposited on the planarized TEOS film 25, then etched via a lithography and etching process using a storage electrode mask as an etching mask to form the hard mask layer pattern 27. Here, the etching process is performed using a mixed gas containing HBr, Cl₂ and O₂.

On the other hand, the etching process causes damage to the hard mask layer pattern 27 denoted as ‘X’, so that a size of the hard mask layer pattern 27 may be smaller than a desired size.

Referring to FIG. 2b, the oxide film is etched using the hard mask layer pattern 27 as an etching mask until a lading plug (not shown) in the lower insulating layer 21 is exposed to form a storage electrode region 29. Here, the size of the hard mask layer pattern 27 is ‘C’ smaller than ‘X’.

Referring to FIG. 2c, the hard mask layer pattern 27 is removed. Thereafter, the storage electrode region 29 is subjected to a cleaning process to increase a surface area of the storage electrode region 29.

At the moment, the removal process of the hard mask layer pattern 27 causes a surface of the TEOS film 25 thereunder to be etched, so as to form the TEOS film pattern 25a with a pointed top.

Next, a planarized conductive layer (not shown) is deposited on the surface of the storage electrode region 29 to form a storage electrode 31.

Here, ‘D’ denotes the bridged neighboring storage electrode 31.

As shown above, in accordance with the above-described conventional method, a bridge of the neighboring storage electrodes occurs, thereby deteriorating the characteristic and reliability of the semiconductor substrate.

Accordingly, it is difficult to obtain high integration density of the semiconductor device.

### SUMMARY OF THE INVENTION

It is an object of the present invention to provide a method for forming a storage electrode of a semiconductor device wherein a surface area of a storage electrode region is increased by etching a surface of a hard mask layer pattern used as an etching mask, thereby preventing a damage to an oxide film for the storage electrode and a bridge between the neighboring storage electrodes.

In order to achieve the object of the present invention, there is provided a method for forming a storage electrode of a semiconductor device comprising the steps:

(a) forming an oxide film on a lower insulating layer disposed on a semiconductor substrate,

(b) forming a hard mask silicide layer pattern defining a strode electrode region on the oxide film,

(c) subjecting the hard mask silicide layer to a cleaning process to recess the hard mask silicide layer pattern, and

(d) etching the oxide film using the recessed hard mask silicide layer pattern as an etching mask until a landing plug is exposed to form a storage electrode.

In order to achieve another object of the present invention, there is provided a method for forming a storage electrode of a semiconductor device comprising the steps:

(a) forming an oxide film on a lower insulating layer disposed on a semiconductor substrate,

(b) forming a hard mask layer pattern defining a strode electrode region on the oxide film,

(c) etching the oxide film using the hard mask layer pattern as a mask until a landing plug is exposed to form a storage electrode region, and

(d) subjecting the hard mask layer pattern to a cleaning process to remove the hard mask layer pattern.

### BRIEF DESCRIPTION OF THE DRAWINGS

FIGS. 1a through 1c are cross-sectional views illustrating a conventional method for forming a storage electrode of a semiconductor device according to an embodiment of the conventional method.

FIGS. 2a through 2c are cross-sectional views illustrating a conventional method for forming a storage electrode of a semiconductor device according to another embodiment of the conventional method.

FIGS. 3a through 3c are cross-sectional views illustrating a method for forming a storage electrode of a semiconductor device according to a first preferred embodiment of the present invention.

FIGS. 4a through 4d are cross-sectional views illustrating a method for forming a storage electrode of a semiconductor device according to a second preferred embodiment of the present invention.

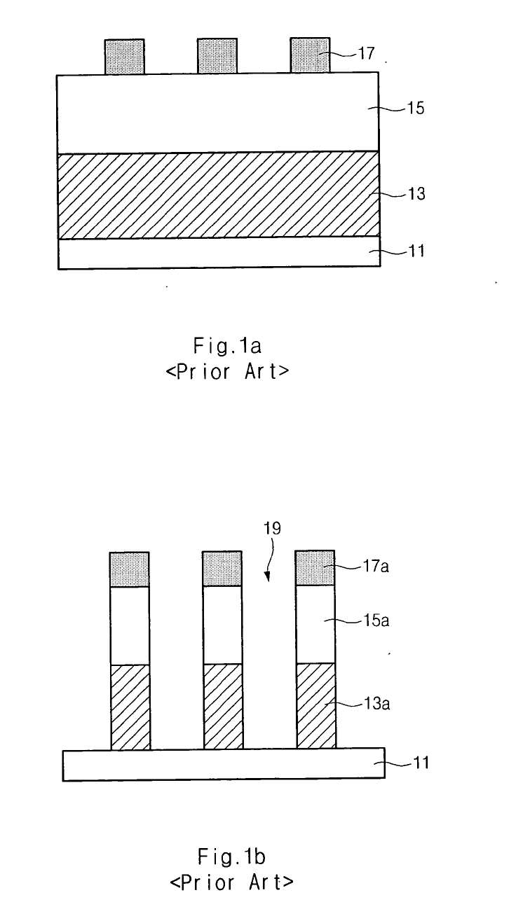

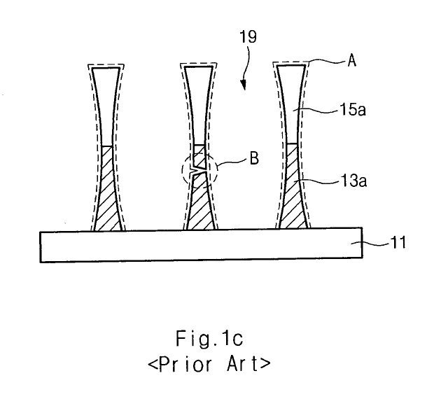

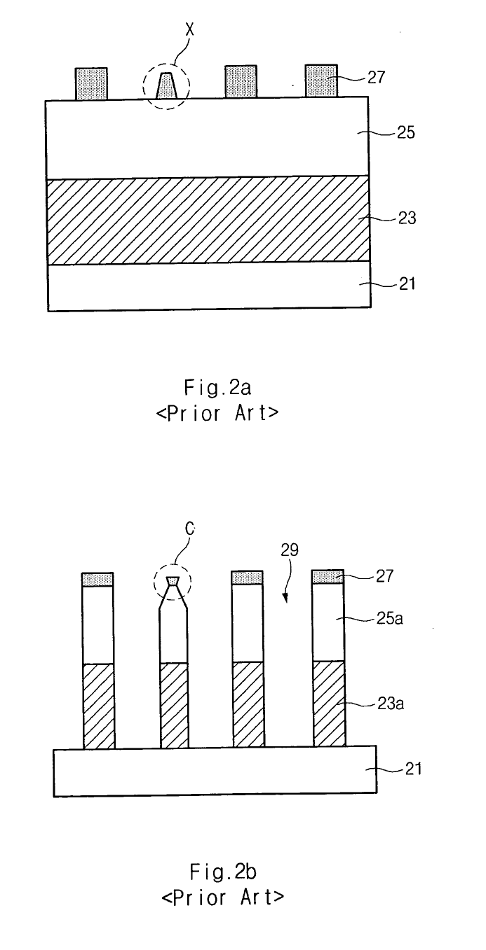

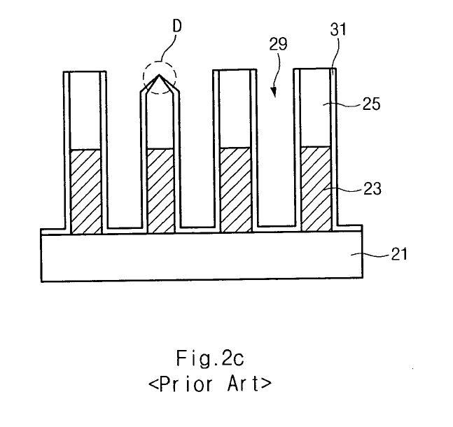

### DETAILED DESCRIPTION OF THE EXEMPLARY EMBODIMENTS

Reference will now be made in detail to exemplary embodiments of the present invention. Wherever possible, the same reference numbers will be used throughout the drawings to refer to the same or like parts.

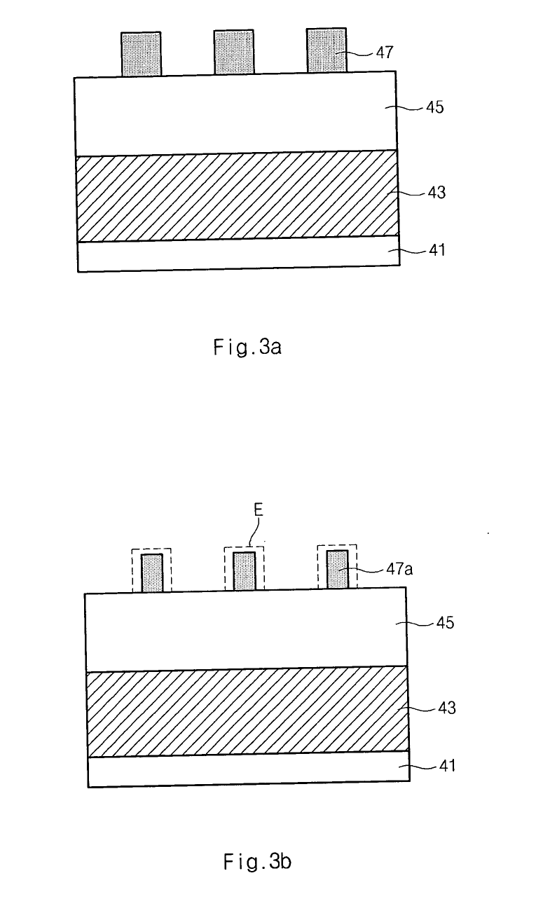

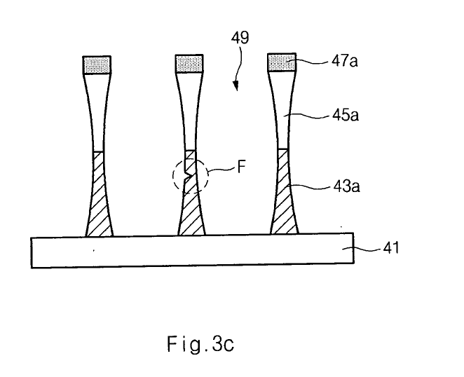

FIGS. 3a through 3c are cross-sectional views illustrating a method for forming a storage electrode of a semiconductor device according to a first preferred embodiment of the present invention.

Referring to FIG. 3a, a lower insulating film 41 is formed on a semiconductor substrate (not shown) including a device isolation film (not shown), a gate electrode (not shown), a landing plug (not shown) and a bit line (not shown).

Next, an oxide film including a stacked structure of a PSG film 43 and a planarized TEOS film 45 is formed on the lower insulating film 41. Here, the TEOS film 45 is formed using a PECVD method.

Thereafter, a hard mask layer pattern 47 defining a storage electrode region 49 is formed on the planarized TEOS film 47.

At the moment, a silicide film (not shown) is deposited on the planarized TEOS film 45, then etched via a lithography and etching process using a storage electrode mask (not shown) to form the hard mask layer pattern 47.

Referring to FIG. 3b, the hard mask layer pattern 47 is subjected to a cleaning process to etch a surface of the hard mask layer pattern 47. As a result, the width of the hard mask silicide layer pattern 47 is reduced. The width of the hard mask silicide layer pattern 47 prior to the etching process is denoted as ‘E’. When the hard mask silicide layer pattern 47a having a reduced width is used as an etching mask in the subsequent etching process of the oxide film, the resulting storage electrode region has a large size.

Preferably, the cleaning process is performed using a mixed solution containing NH₄OH, H₂O₂ and H₂O, a mixed solution containing HCl, H₂O₂ and H₂O, or combinations thereof.

Moreover, a ratio of NH₄OH, H₂O₂ and H₂O in the mixed solution containing NH₄OH, H₂O₂ and H₂O having a temperature equal to or greater than 25° C. preferably ranges from 1:2:15 to 1:5:25, and a ratio of HCl, H₂O₂ and H₂O in the mixed solution containing HCl, H₂O₂ and H₂O having a temperature equal to or greater than 70° C. preferably ranges from 1:3:300 to 1:6:700.

On the other hand, an etching ratio of the hard mask layer pattern 47 to the TEOS film 45 preferably is 16:1, and the time period for the cleaning process may be adjusted according to the size of the storage electrode.

Referring to FIG. 3c, the oxide film is etched using the hard mask layer pattern 47a having a reduced size as an etching mask until a landing plug (not shown) in the lower insulating film 41 is exposed to form the storage electrode region 49.

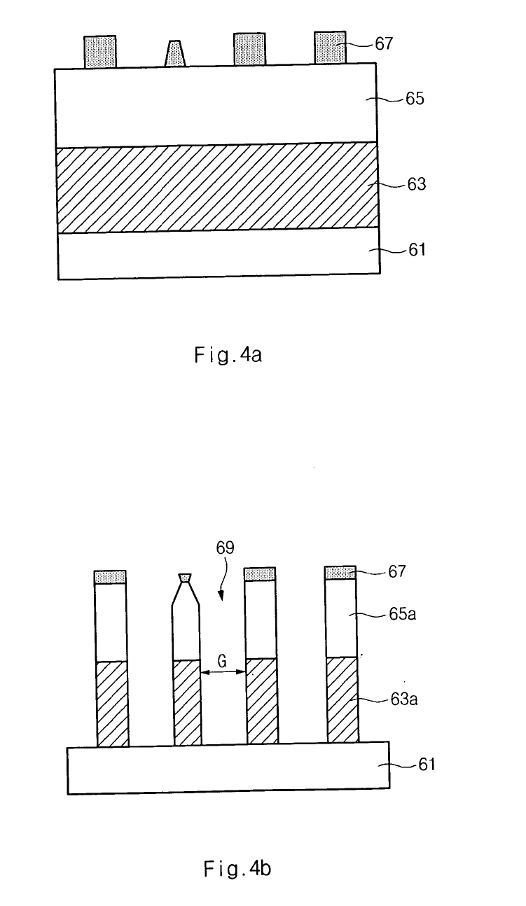

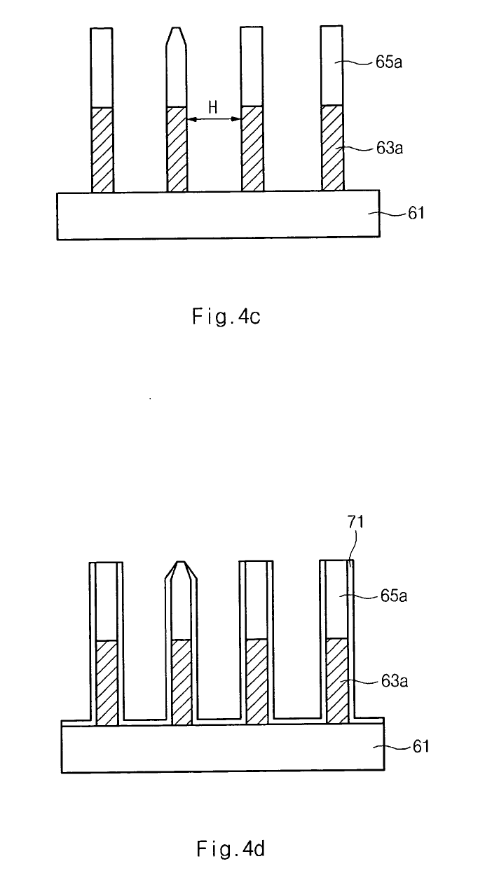

FIGS. 4a through 4d are cross-sectional views illustrating a method for forming a storage electrode of a semiconductor device according to a second preferred embodiment of the present invention.

Referring to FIG. 4a, a lower insulating film 61 is formed on a semiconductor substrate (not shown) including a device isolation film (not shown), a gate electrode (not shown), a landing plug (not shown) and a bit line (not shown).

Next, an oxide film including a stacked structure of a PSG film 63 and a planarized TEOS film 65 is formed on the lower insulating film 61. Here, the TEOS film 65 is formed using a PECVD method.

Thereafter, a hard mask layer pattern 67 defining a storage electrode region 69 is formed on the planarized TEOS film 67.

Here, the hard mask layer pattern 67 is preferably a metal layer. More preferably, the hard mask layer pattern 67 comprises a titanium layer, a tungsten layer, a tungsten nitride, and combinations thereof.

On the other hand, the hard mask layer pattern 67 may be subjected to a cleaning process using a BOE to etch a surface of the hard mask layer pattern 67. As a result, the width of the hard mask layer pattern 67 is reduced.

Referring to FIG. 4b, the oxide film is etched using the reduced hard mask layer pattern 67 as an etching mask until the landing plug (not shown) in the lower insulating film 61 is exposed to form the storage electrode region 69. Here, a width of the storage electrode region 69 is ‘G’.

Referring to FIG. 4c, the storage electrode region 69 including the hard mask layer pattern 67 is subjected to a cleaning process to remove the hard mask layer pattern 67. Here, the width of the storage electrode region 69 is increased to ‘H’ during the cleaning process. The hard mask layer pattern 67 is then removed meanwhile.

At this time, the cleaning process is performed using a mixed solution containing NH₄OH, H₂O₂ and H₂O, and a ratio of NH₄OH, H₂O₂ and H₂O in the mixed solution containing NH₄OH, H₂O₂ and H₂O having a temperature ranging from 40° C. to 90° C. preferably ranges from 1:2:15 to 1:6:30.

Moreover, an etching ratio of the hard mask layer pattern to the oxide layer preferably ranges from 1:1300 to 4:8100. Preferably, an etching ratio over a silicon oxide film, the TEOS film, BPSG, a titanium film, a tungsten film and a tungsten nitride film is 1:4:135:1308:1961:8087, respectively.

Referring to FIG. 4d, a planarized conductive layer (not shown) is formed on the surface of the storage electrode region 69 to form a storage electrode 71.

Here, the TEOS film pattern 65a in the hard mask layer pattern 67 damaged as shown in FIG. 4b has any more damage in the subsequent process, thereby preventing the bridge between the neighboring storage electrodes 71.

As described above, the method for forming a storage electrode of a semiconductor device in accordance with the present invention provides preventing the bridge between the neighboring storage electrodes. Accordingly, there is an effect to obtain sufficient electrostatic capacitance during the fabrication process of the semiconductor device.

The foregoing description of various embodiments of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated.

What is claimed is:

1. A method for forming a storage electrode of a semiconductor device, comprising the steps of:
(a) forming an oxide film on a lower insulating layer disposed on a semiconductor substrate;
(b) forming a hard mask silicide layer pattern defining a strode electrode region on the oxide film;
(c) subjecting the hard mask silicide layer to a cleaning process to recess the hard mask silicide layer pattern; and
(d) etching the oxide film using the recessed hard mask silicide layer pattern as an etching mask until a landing plug is exposed to form a storage electrode.

2. The method according to claim 1, wherein the cleaning process is performed using a solution selected from the group consisting of a mixed solution containing NH₄OH, H₂O₂ and H₂O, a mixed solution containing HCl, H₂O₂ and H₂O, and combinations thereof.

3. The method according to claim 2, wherein a ratio of the mixed solution containing NH₄OH, H₂O₂ and H₂O having a temperature equal to and greater than 25° C. ranges from 1:2:15 to 1:5:25.

4. The method according to claim 2, wherein a ratio of the mixed solution containing HCl, H₂O₂ and H₂O having a temperature equal to and greater than 70° C. ranges from 1:3:300 to 1:6:700.

5. The method according to claim 2, wherein a ratio of an etching rate of the hard mask silicide layer pattern to that of the oxide film is 1.6:1.

6. A method for forming a storage electrode of a semiconductor device, comprising the steps of:
(a) forming an oxide film on a lower insulating layer disposed on a semiconductor substrate;
(b) forming a hard mask layer pattern defining a strode electrode region on the oxide film;
(c) etching the oxide film using the hard mask layer pattern as a mask until a landing plug is exposed to form a storage electrode region; and
(d) subjecting the hard mask layer pattern to a cleaning process to remove the hard mask layer pattern.

7. The method according to claim 6, wherein the hard mask layer pattern is a metal layer.

8. The method according to claim 6, wherein the hard mask layer pattern comprises a layer selected from the group consisting of a titanium layer, a tungsten layer, a tungsten nitride and combinations thereof.

9. The method according to claim 6, wherein the cleaning process is performed using a mixed solution containing NH₄OH, H₂O₂ and H₂O.

10. The method according to claim 9, wherein a ratio of the mixed solution having a temperature ranging from 40° C. to 90° C. ranges from 1:2:15 to 1:6:30.

11. The method according to claim 6, wherein a ratio of an etching rate of the hard mask layer pattern to that of the oxide film ranges from 1:1300 to 4:8100.
